(19) United States
(12) Patent Application Publication
(10) Pub. No.: US 2026/0096334 A1
(43) Pub. Date: Apr. 2, 2026

(54) LIGHT EMITTING DEVICE, MANUFACTURING METHOD THEREOF, AND DEVICE INCLUDING LIGHT EMITTING DEVICE

(71) Applicant: CANON KABUSHIKI KAISHA, Tokyo (JP)

(72) Inventors: DAISUKE OKABAYASHI, Kanagawa (JP); AKINORI MAKAINO, Kanagawa (JP)

(21) Appl. No.: 19/333,675

(22) Filed: Sep. 19, 2025

(30) Foreign Application Priority Data
Sep. 30, 2024 (JP) 2024-171516

(51) Int. Cl. H10K 59/80; H10K 59/12

(52) U.S. Cl. CPC H10K 59/878; H10K 59/1201; H10K 59/80518

(57) ABSTRACT

A light emitting device includes a plurality of sub-pixels. A first sub-pixel includes a first lower electrode and a first reflecting member below the first lower electrode, and a second sub-pixel includes a second lower electrode and a second reflecting member below the second lower electrode. The device includes an insulating film covering the first reflecting member and the second reflecting member. The insulating film is formed of a cured product of a curable composition, the insulating film includes a first portion arranged between the first reflecting member and the first lower electrode, and a second portion arranged between the second reflecting member and the second lower electrode, and a thickness of the first portion is different from a thickness of the second portion.

### BACKGROUND

### Field of the Technology

The present disclosure relates to a light emitting device, a manufacturing method thereof, and a device including the light emitting device.

### Description of the Related Art

Japanese Patent Laid-Open No. 2021-72282 describes an organic device that includes an optical adjustment film formed of an SiO₂ film between a lower electrode and a reflecting member of each of a red light emitting pixel, a green light emitting pixel, and a blue light emitting pixel, and a manufacturing method thereof. The optical adjustment film of each of the red light emitting pixel, the green light emitting pixel, and the blue light emitting pixel is a film that defines the distance between the lower electrode and the reflecting member, and has a different thickness for each color of the light emitting pixel. The different thicknesses are implemented by repeating a film formation step, a photolithography step, and an etching step.

In a case where optical adjustment films having thicknesses different from each other are implemented by repeating a film formation step, a photolithography step, and an etching step, there are problems that the number of steps is large and the manufacturing cost is high.

### SUMMARY

The present disclosure incudes a technique advantageous in reducing the manufacturing cost of a light emitting device in which the distance between a lower electrode and a reflecting member is different among sub-pixels that emit light components of different colors.

The present disclosure includes a light emitting device that includes a plurality of sub-pixels each including a lower electrode and an upper electrode, the plurality of sub-pixels including a first sub-pixel and a second sub-pixel, the first sub-pixel including a first reflecting member below a first lower electrode serving as a lower electrode of the first sub-pixel, and the second sub-pixel including a second reflecting member below a second lower electrode serving as a lower electrode of the second sub-pixel, the device comprising an insulating film covering the first reflecting member and the second reflecting member, wherein the insulating film is formed of a cured product of a curable composition, the insulating film includes a first portion arranged between the first reflecting member and the first lower electrode, and a second portion arranged between the second reflecting member and the second lower electrode, and a thickness of the first portion and a thickness of the second portion are different from each other.

Features of the present disclosure will become apparent from the following description of embodiments with reference to the attached drawings.

### BRIEF DESCRIPTION OF THE DRAWINGS

FIG. 1 is a view schematically showing the arrangement of a light emitting device according to an embodiment;

FIG. 2 is a view schematically showing another arrangement of the light emitting device according to the embodiment;

FIG. 3 is a view schematically showing an example of the arrangement of an imprint apparatus that can be used to form an insulating film (optical adjustment film) which defines the spacing between a reflecting member and a lower electrode;

FIG. 4 is a schematic sectional view for explaining a manufacturing method of the light emitting device;

FIG. 5 is a schematic sectional view for explaining the manufacturing method of the light emitting device;

FIG. 6 is a schematic sectional view for explaining the manufacturing method of the light emitting device;

FIG. 7 is a schematic sectional view for explaining the manufacturing method of the light emitting device;

FIG. 8 is a schematic sectional view for explaining the manufacturing method of the light emitting device;

FIG. 9 is a schematic sectional view for explaining the manufacturing method of the light emitting device;

FIG. 10 is a schematic sectional view for explaining the manufacturing method of the light emitting device;

FIG. 11 is a schematic sectional view for explaining the manufacturing method of the light emitting device;

FIG. 12 is a schematic sectional view for explaining the manufacturing method of the light emitting device;

FIGS. 13A to 13C are views exemplifying a mold replication step;

FIGS. 14A and 14B are views exemplifying an application example of the light emitting device;

FIGS. 15A to 15C are views exemplifying an application example of the light emitting device;

FIG. 16 is a view exemplifying an application example of the light emitting device;

FIG. 17 is a view exemplifying an application example of the light emitting device;

FIG. 18 is a view exemplifying an application example of the light emitting device;

FIGS. 19A and 19B are views each exemplifying an application example of the light emitting device;

FIG. 20 is a view exemplifying an application example of the light emitting device;

FIG. 21 is a view exemplifying an application example of the light emitting device; and

FIGS. 22A and 22B are views each exemplifying an application example of the light emitting device.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

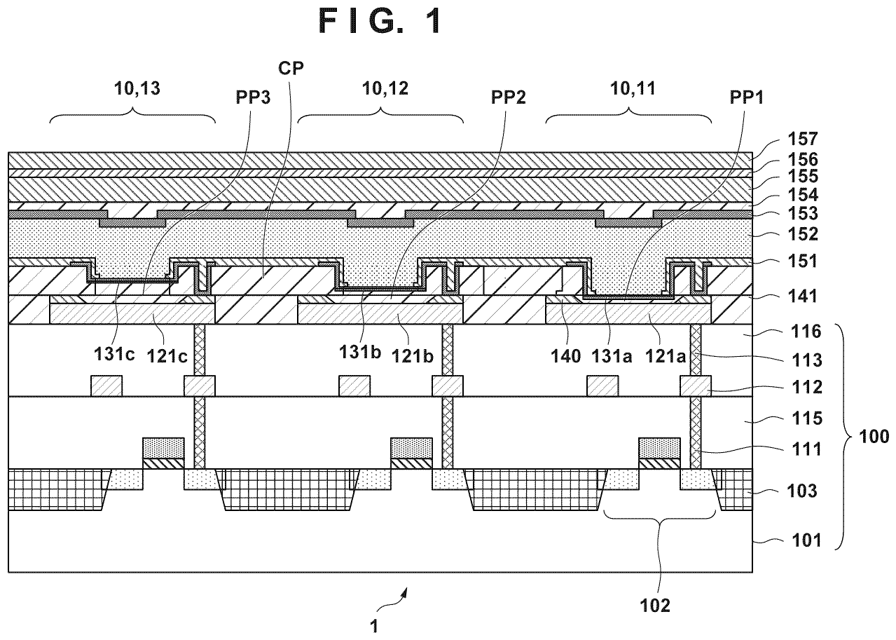

FIG. 1 schematically shows the arrangement of a light emitting device 1 according to an embodiment. The light emitting device 1 can be formed as a device called an organic light emitting device, an organic EL device, or an OLED. The light emitting device 1 can be formed as a display device. The light emitting device 1 includes a plurality of pixels, and each pixel can include a plurality of sub-pixels 10. In one aspect, the plurality of sub-pixels 10 can include a first sub-pixel 11 and a second sub-pixel 12. In another aspect, the plurality of sub-pixels 10 can include the first sub-pixel 11, the second sub-pixel 12, and a third sub-pixel 13. The first sub-pixel 11, the second sub-pixel 12, and the third sub-pixel 13 are sub-pixels that generate light components of colors (wavelength bands) different from each other. Each pixel may include more sub-pixels. In an example, the first sub-pixel 11 is a sub-pixel that generates blue light, the second sub-pixel 12 is a sub-pixel that generates green light, and the third sub-pixel 13 is a sub-pixel that generates red light. Note that FIG. 1 shows only one first sub-pixel 11, one second sub-pixel 12, and one third sub-pixel 13, but the light emitting device 1 is formed to include more sub-pixels 10 in accordance with an application purpose.

The first sub-pixel 11 can include a first reflecting member 121a and a first lower electrode 131a. The second sub-pixel 12 can include a second reflecting member 121b and a second lower electrode 131b. The third sub-pixel 13 can include a third reflecting member 121c and a third lower electrode 131c. Here, when expressing the first reflecting member 121a, the second reflecting member 121b, and the third reflecting member 121c without distinguishing them from each other, they are referred to as reflecting members 121. Similarly, when expressing the first lower electrode 131a, the second lower electrode 131b, and the third lower electrode 131c without distinguishing them from each other, they are referred to as lower electrodes 131. For example, the reflecting member 121 can be made of Ti, Al, or AlCu, or have a stacked structure of Ti/AlCu.

The sub-pixel 10 includes the lower electrode 131 and an upper electrode 153. In the example shown in FIG. 1, the upper electrodes 153 of the plurality of sub-pixels 10 are provided commonly for the plurality of sub-pixels 10. However, the upper electrodes 153 of the plurality of sub-pixels 10 may be provided individually for the plurality of sub-pixels 10. In such a case, the individual upper electrode 153 can be electrically connected to the reflecting member 121 or a driving element arranged below it, and the lower electrodes 131 of the plurality of sub-pixels 10 can be provided commonly for the plurality of sub-pixels 10.

The reflecting members 121 of the plurality of sub-pixels 10 can be arranged on a substrate 100. The lower electrodes 131 of the plurality of sub-pixels 10 can be driven by driving elements such as transistors 102 arranged in the substrate 100. The substrate 100 can include, for example, a semiconductor substrate 101 where a plurality of transistors 102 are arranged, interlayer insulating films 115 and 116, vias 111 and 113, and a wiring layer (wiring pattern) 112.

In each sub-pixel 10, as exemplified in FIG. 1, the reflecting member 121 and the lower electrode 131 arranged above it can be electrically connected via, for example, a barrier metal 140. Alternatively, the reflecting member 121 may be electrically insulated from the lower electrode 131, and a fixed potential may be applied to the reflecting member 121. The barrier metal 140 can be formed of, for example, Ti, TiN, or a stacked film of Ti/TiN.

An insulating film 141 is arranged between the reflecting member 121 and the lower electrode 131. The insulating film 141 is arranged between the reflecting member 121 and the lower electrode 131, and can also be arranged between the reflecting members 121 adjacent to each other. In each sub-pixel 10, the insulating film 141 is arranged so as to define the spacing (optical distance) between the reflecting member 121 and the lower electrode 131, so that it can function as an optical adjustment film for allowing radiation of light of a specific wavelength band from the sub-pixel 10. More specifically, in the first sub-pixel 11 that can be configured as a blue sub-pixel, the spacing (optical distance) between the first reflecting member 121a and the first lower electrode 131a is decided so as to allow radiation of blue light from the first sub-pixel 11. In the second sub-pixel 12 that can be configured as a green sub-pixel, the spacing (optical distance) between the second reflecting member 121b and the second lower electrode 131b is decided so as to allow radiation of green light from the second sub-pixel 12. In the third sub-pixel 13 that can be configured as a red sub-pixel, the spacing (optical distance) between the third reflecting member 121c and the third lower electrode 131c is decided so as to allow radiation of red light from the third sub-pixel 13. The insulating film 141 can be formed of a material that transmits light of a visible light band. As will be described later in detail, the insulating film 141 can be formed by an imprint process.

The insulating film 141 can include a first portion PP1 arranged between the first reflecting member 121a and the first lower electrode 131a, and a second portion PP2 arranged between the second reflecting member 121b and the second lower electrode 131b. The thickness of the first portion PP1 and the thickness of the second portion PP2 can be different from each other. In another viewpoint, the spacing between the first reflecting member 121a and the first lower electrode 131a and the spacing between the second reflecting member 121b and the second lower electrode 131b can be different from each other. The insulating film 141 can also include a connecting portion CP connecting the first portion PP1 and the second portion PP2. The distance between the upper surface of the connecting portion CP and the upper surface of the substrate 100 is larger than the distance between the upper surface of the first portion PP1 and the upper surface of the substrate 100 and the distance between the upper surface of the second portion PP2 and the upper surface of the substrate 100.

The insulating film 141 can further include a third portion PP3 arranged between the third reflecting member 121c and the third lower electrode 131c. The thickness of the first portion PP1, the thickness of the second portion PP2, and the thickness of the third portion PP3 can be different from each other. In another viewpoint, the spacing between the first reflecting member 121a and the first lower electrode 131a, the spacing between the second reflecting member 121b and the second lower electrode 131b, and the spacing between the third reflecting member 121c and the third lower electrode 131c can be different from each other. The connecting portion CP can connect the first portion PP1, the second portion PP2, and the third portion PP3. The distance between the upper surface of the connecting portion CP and the upper surface of the substrate 100 is larger than the distance between the upper surface of the first portion PP1 and the upper surface of the substrate 100, the distance between the upper surface of the second portion PP2 and the upper surface of the substrate 100, and the distance between the upper surface of the third portion PP3 and the upper surface of the substrate 100.

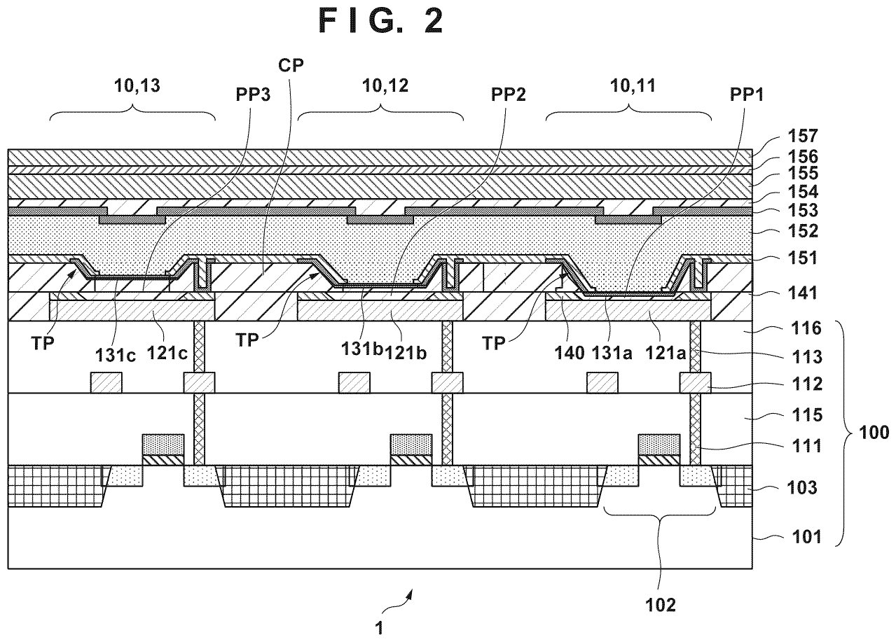

As schematically shown in FIG. 2, the first lower electrode 131a can have a tapered shape where the width of the first lower electrode 131a in a direction parallel to the upper surface of the substrate 100 increases as the distance from the first reflecting member 121a increases. The second lower electrode 131b can have a tapered shape where the width of the second lower electrode 131b in a direction parallel to the upper surface of the substrate 100 increases as the distance from the second reflecting member 121b increases. The third lower electrode 131c can have a tapered shape where the width of the third lower electrode 131c in a direction parallel to the upper surface of the substrate 100 increases as the distance from the third reflecting member 121c increases. The upper surface of the insulating film 141 can have tapered surfaces TP between the upper surface of the connecting portion CP and the upper surface of the first portion PP1, between the upper surface of the connecting portion CP and the upper surface of the second portion PP2, and between the upper surface of the connecting portion CP and the upper surface of the third portion PP3. The angle formed by the upper surface of the connecting portion CP and the tapered surface TP is, for example, within a range of 30° to 60°, and preferably a range of 40° to 50°, and the nominal value can be 45°. Such the angle is advantageous for suppressing AC leakage. According to an imprint process, such the structure can be formed with ease and high reproducibility. An insulating film 151 can be arranged to cover a peripheral portion of the upper surface of each of the plurality of lower electrodes 131 and the insulating film 141 among the plurality of lower electrodes 131.

An organic compound layer 152 is arranged between the lower electrode 131 and the upper electrode 153. The organic compound layer 152 can be arranged to cover the plurality of lower electrodes 131 and the insulating film 151. The organic compound layer 152 can include, for example, a hole injection layer, a hole transport layer, an electron blocking layer, a light emitting layer, a hole blocking layer, an electron transport layer, an electron injection layer, and the like. For example, a planarizing film 154 can be arranged on the upper electrode 153. However, the planarizing film 154 is unnecessary if the upper surface of the upper electrode 153 is sufficiently flat. One or a plurality of sealing films can be arranged on the planarizing film 154. In an example, a first sealing film 155, a second sealing film 156, and a third sealing film 157 can be arranged on the planarizing film 154. The first sealing film 155 is, for example, silicon nitride. The second sealing film 156 is, for example, an aluminum oxide film. The third sealing film is, for example, silicon nitride. On these sealing films, a color filter array and/or a microlens array may be arranged.

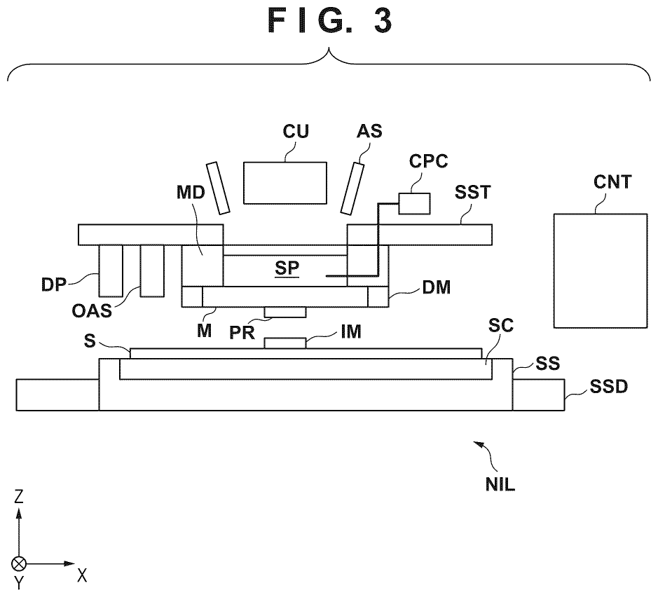

FIG. 3 schematically shows an example of the arrangement of an imprint apparatus NIL that can be used to form the insulating film 141. The imprint apparatus NIL is an apparatus that transfers the pattern of a mold M to a curable composition IM on a substrate S. As the curable composition IM, a composition (to be also referred to as a resin in an uncured state) to be cured by receiving curing energy is used. As the curing energy, an electromagnetic wave, heat, or the like is used. The electromagnetic wave is light selected from the wavelength range of 10 nm (inclusive) to 1 mm (inclusive), for example, infrared light, a visible light beam, ultraviolet light, or the like. The curable composition IM may be understood as a composition cured by light irradiation or a composition cured by heating. Among these, a photo-curable composition cured by light contains at least a polymerizable compound and a photopolymerization initiator, and may contain a nonpolymerizable compound or a solvent, as needed. The nonpolymerizable compound is at least one material selected from the group consisting of a sensitizer, a hydrogen donor, an internal mold release agent, a surfactant, an antioxidant, and a polymer component. The curable composition IM can be applied, onto the substrate, in a film shape by a spin coater or a slit coater. The curable composition IM may be applied, onto the substrate, in a droplet shape or in an island or film shape formed by connecting a plurality of droplets using a liquid injection head. The viscosity (the viscosity at 25° C.) of the curable composition IM is, for example, 1 mPa·s (inclusive) to 100 mPa·s (inclusive).

The imprint apparatus NIL can include a substrate stage SS including a substrate chuck SC that holds the substrate S, and a substrate driving mechanism SD that drives the substrate stage SS. The imprint apparatus NIL can also include a mold driving mechanism MD that holds and drives the mold M. The substrate driving mechanism SD and the mold driving mechanism MD constitute a relative driving mechanism that drives at least one of the substrate S and the mold M to adjust the relative position between the substrate S and the mold M. Adjustment of the relative position by the relative driving mechanism includes driving for bringing the mold M into contact with the curable composition IM on the substrate S and driving for separating the mold M from the cured product (the pattern of the cured product) of the curable composition IM. Adjustment of the relative position by the relative driving mechanism also includes alignment between the substrate S (a shot region thereof) and the mold M (a pattern region PR thereof). The substrate driving mechanism SD can be configured to drive the substrate S with respect to a plurality of axes (for example, three axes including the X-axis, Y-axis, and θZ-axis, and preferably six axes including the X-axis, Y-axis, Z-axis, θX-axis, θY-axis, and θZ-axis). The imprint apparatus NIL can include a mold deformation mechanism DM that deforms the two-dimensional shape of the pattern region PR of the mold M. The mold deformation mechanism DM can deform the pattern region PR of the mold M by, for example, applying a force to the side surface of the mold M. The mold driving mechanism MD can be configured to drive the mold M with respect to a plurality of axes (for example, three axes including the Z-axis, θX-axis, and θY-axis, and preferably six axes including the X-axis, Y-axis, Z-axis, θX-axis, θY-axis, and θZ-axis). The imprint apparatus NIL can include a pressure controller CPC that controls the three-dimensional shape of the pattern region PR of the mold M by adjusting the pressure in a sealed space SP formed on the back surface of the mold M. It is possible to deform the pattern region PR of the mold M into a downward convex shape or planarize it by adjusting the pressure in the sealed space SP by the pressure controller CPC.

The imprint apparatus NIL can include one or a plurality of alignment scopes AS for measuring the alignment error between the shot region of the substrate S and the pattern region PR of the mold M. The imprint apparatus NIL can include a curing unit CU that forms a cured pattern by curing the curable composition IM by applying curing energy to the curable composition IM via the mold M. The imprint apparatus NIL can include a dispenser DP that applies or arranges the curable composition IM onto the substrate S. The imprint apparatus NIL can include an off-axis scope OAS for detecting the position of the alignment mark of the substrate S. The imprint apparatus NIL can include a control unit CNT that controls the respective components of the imprint apparatus NIL. The control unit CNT is an information processing apparatus that can be formed from, for example, a PLD (the abbreviation of Programmable Logic Device) such as an FPGA (the abbreviation of Field Programmable Gate Array), an ASIC (the abbreviation of Application Specific Integrated Circuit), a computer incorporating a program, or a combination of some or all of these.

A manufacturing method of the light emitting device 1 will be exemplarily described below. First, with reference to FIGS. 1 and 2, a manufacturing method of the substrate 100 will be described. First of all, elements such as the plurality of transistors 102 electrically isolated from each other by element isolations 103 can be formed in the semiconductor substrate 101. Then, the interlayer insulating films 115 and 116, the vias 111 and 113, the wiring layer 112, and the like are formed.

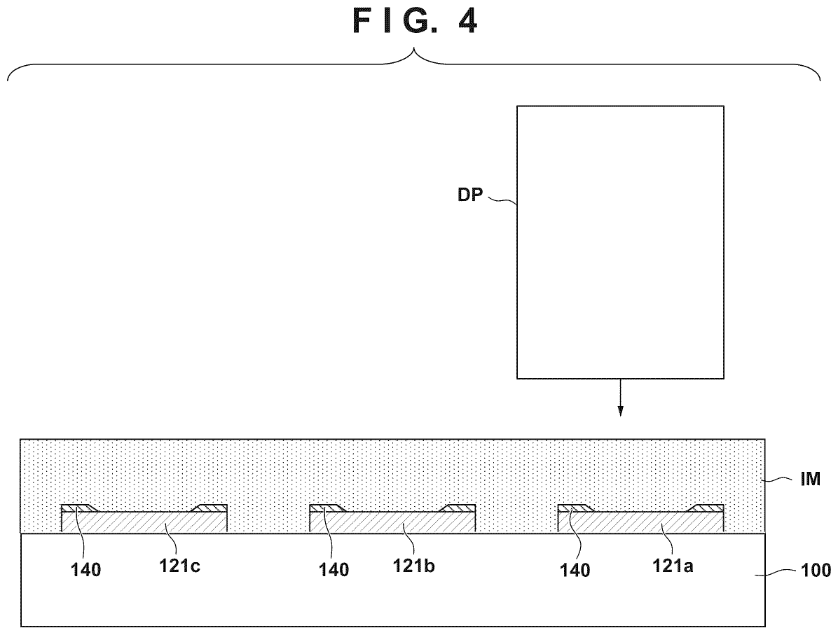

The process from a step of forming the reflecting members 121 to a step of forming the lower electrodes 131 will be exemplarily described below with reference to FIGS. 4 to 12. First, as schematically shown in FIG. 4, the plurality of reflecting members 121 including the first reflecting member 121a, the second reflecting member 121b, and the third reflecting member 121c can be formed on the substrate 100. The barrier metal 140 can be formed to cover the peripheral portion of each reflecting member 121. Then, in the imprint apparatus NIL, a step of arranging the curable composition IM by the dispenser DP so as to cover the substrate 100, the reflecting members 121, and the barrier metals 140 is executed.

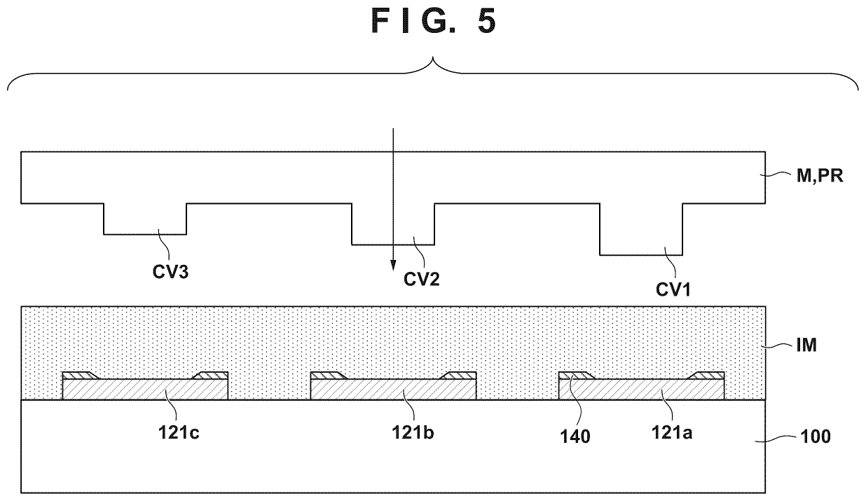

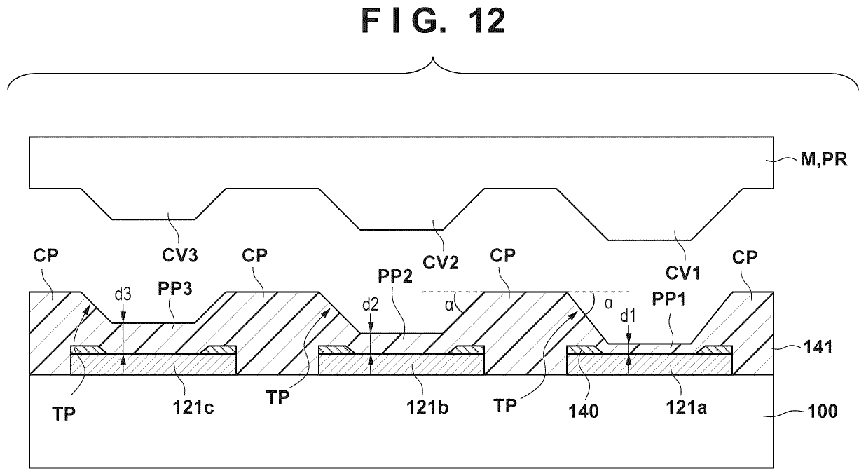

Then, as schematically shown in FIG. 5, in the imprint apparatus NIL, a step of bringing the pattern region PR of the mold M into contact with the curable composition IM arranged to cover the substrate 100, the reflecting members 121, and the barrier metals 140 is executed. The pattern region of the mold M can include a first convex portion CV1, a second convex portion CV2, and a third convex portion CV3 for forming the first portion PP1, the second portion PP2, and the third portion PP3, respectively. When forming the insulating film 141 including the tapered surfaces TP or the lower electrodes 131 each having the tapered shape as schematically shown in FIG. 2, the mold M including the first tapered convex portion CV1, the second tapered convex portion CV2, and the third tapered convex portion CV3 as schematically shown in FIG. 12 is used.

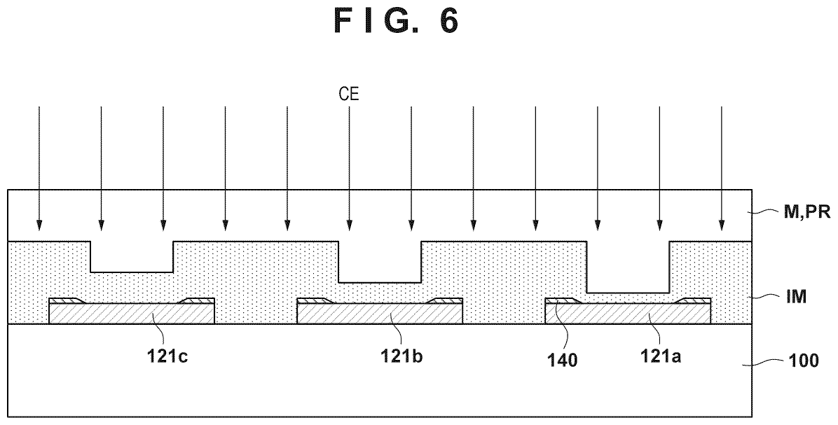

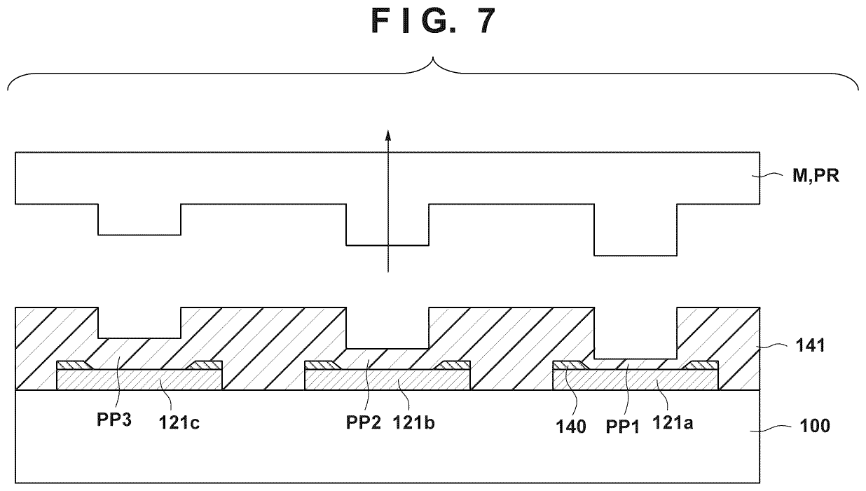

Then, as schematically shown in FIG. 6, a step of curing the curable composition IM by the curing unit CU in a state in which the curable composition IM and the mold M are in contact with each other is executed. With this, the insulating film 141 made of the cured product of the curable composition IM is formed. Then, as schematically shown in FIG. 7, a step of separating the mold M from the insulating film 141 is executed.

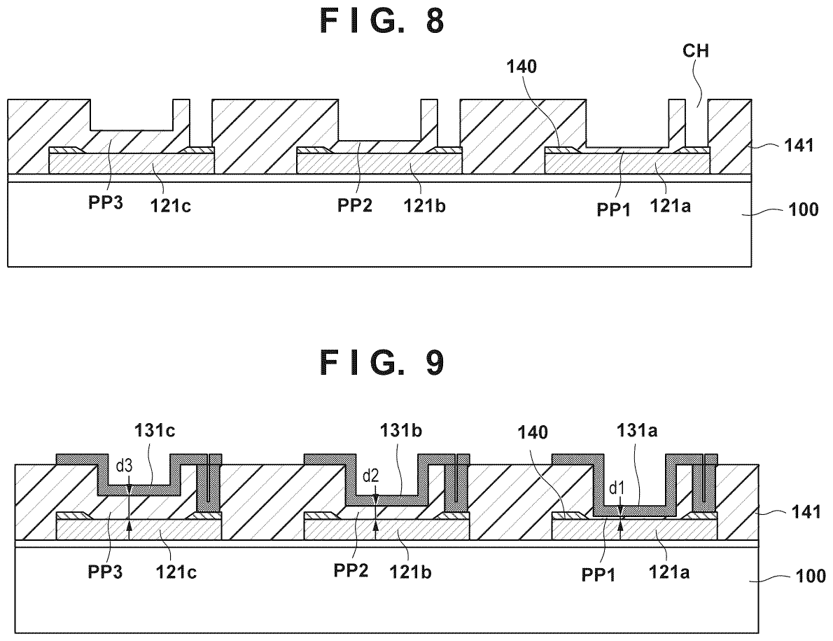

Then, as schematically shown in FIG. 8, steps (a photolithography step and an etching step) for forming contact holes CH for electrically connecting the reflecting members 121 and the lower electrodes 131 can be executed. Note that in a case where the reflecting members 121 are not electrically connected to the lower electrodes 131, these steps are unnecessary. Instead of the steps for forming the contact holes CH, a pattern for forming the contact holes CH may be provided in the mold M. In this case, it is possible to form the contact holes together with the first portion PP1, the second portion PP2, and the third portion PP3.

Then, as schematically shown in FIG. 9, a step of forming the lower electrodes 131 above the reflecting members 121 via the insulating film 141 can be executed. In one viewpoint, in this step, the first lower electrode 131a and the second lower electrode 131b can be formed above the first reflecting member 121a and the second reflecting member 121b, respectively, via the insulating film 141. A spacing d1 between the first reflecting member 121a and the first lower electrode 131a and a spacing d2 between the second reflecting member 121b and the second lower electrode 131b are different from each other. In another viewpoint, in this step, the first lower electrode 131a, the second lower electrode 131b, and the third lower electrode 131c can be formed above the first reflecting member 121a, the second reflecting member 121b, and the third reflecting member 121c, respectively, via the insulating film 141. The spacing d1 between the first reflecting member 121a and the first lower electrode 131a, the spacing d2 between the second reflecting member 121b and the second lower electrode 131b, and a spacing d3 between the third reflecting member 121c and the third lower electrode 131c are different from each other.

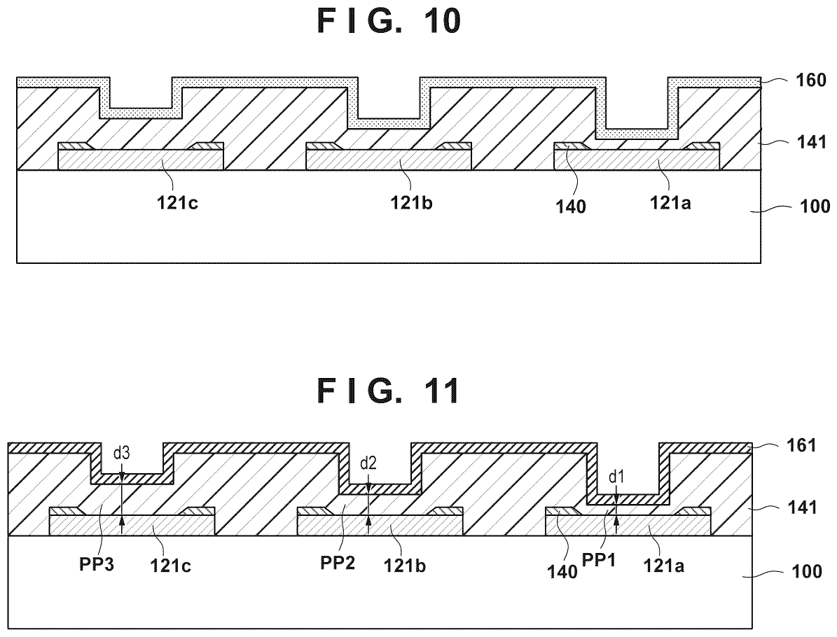

In the step shown in FIG. 7, that is, in the step of separating the mold M from the insulating film 141, a mold release agent film 160 may remain as schematically shown in FIG. 10. In this case, the subsequent step may be executed after the mold release agent film 160 is removed, or the subsequent step may be executed without removing the mold release agent film 160. In the latter case, the mold release agent film 160 can remain between the insulating film 141 and the lower electrodes 131 of the plurality of sub-pixels 10. Examples of the mold release agent are a silicon-based mold release agent, a fluorine-based mold release agent, a polyethylene-based mold release agent, a polypropylene-based mold release agent, a paraffine-based mold release agent, a montane-based mold release agent, and a carnauba-based mold release agent. Among these, the fluorine-based mold release agent is particularly favorable. In a case where the mold release agent is to remain, the adhesion with the lower electrodes to be formed in the subsequent step may be improved. On the other hand, in a case where the fluorine-based mold release agent is used, the mold release agent is preferably reduced so as not to influence the organic layer of an OLED. More specifically, the mold release agent may be 0.01 g/cm³ or more and 1 g/cm³ or less. Fluorine atoms may be at 0.01 at % or more and 1 at % or less.

After the step shown in FIG. 7, that is, after the step of separating the mold M from the insulating film 141 and before the step of forming the lower electrodes 131, a second insulating film 161 may be formed on the insulating film 141 as schematically shown in FIG. 11. In this case, the spacing d1 is the sum of the film thickness of the first portion PP1 and the film thickness of the second insulating film 161, the spacing d2 is the sum of the film thickness of the second portion PP2 and the film thickness of the second insulating film 161, and the spacing d3 is the sum of the film thickness of the third portion PP3 and the film thickness of the second insulating film 161. The second insulating film 161 can be an inorganic film. The inorganic film as the second insulating film 161 can be a film made of, for example, silicon oxide, silicon oxynitride, or silicon nitride. If the mold release agent film 160 remains in the step of separating the mold M from the insulating film 141, the second insulating film 161 may be formed on the mold release agent film 160.

Alternatively, after the step shown in FIG. 7, that is, after the step of separating the mold M from the insulating film 141 and before the step of forming the lower electrodes 131, the insulating film 141 may be etched by required thicknesses to adjust the film thicknesses of the first portion PP1, the second portion PP2, and the third portion PP3.

With reference to FIGS. 1 and 2, steps for forming the structure above the lower electrodes 131 will be exemplarily described below. The organic compound layer 152 is arranged on the lower electrodes 131. The organic compound layer 152 can include, for example, a hole injection layer, a hole transport layer, an electron blocking layer, a light emitting layer, a hole blocking layer, an electron transport layer, an electron injection layer, and the like. Then, the upper electrode 153 is formed, the planarizing film 154 is formed thereon, as needed, and the sealing films (for example, sealing films 155, 156, and 157) can further be formed. On the sealing films, a color filter array and/or a microlens array may be arranged.

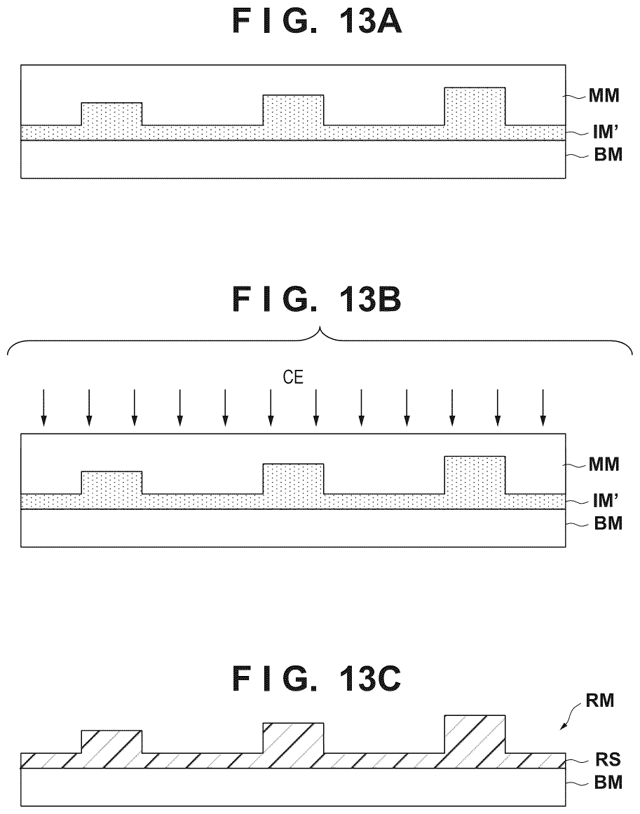

The mold M can be degraded through contact with the curable composition IM and separation from the cured product of the curable composition IM. To prevent this, the manufacturing method of the light emitting device 1 may further include a replication step of forming the mold M by replicating a master structure by an imprint process. With reference to FIGS. 13A to 13C, the replication step will be exemplarily described.

First, as schematically shown in FIG. 13A, a step of making a master mold MM serving as a master structure and a blank mold BM face each other via a second curable composition IM′ can be executed. The second curable composition IM′ may have the same composition as the curable composition IM described above, or may have a different composition. Then, as schematically shown in FIG. 13B, the second curable composition IM′ is cured. Thus, a step of forming a replica structure RS formed of a cured film of the second curable composition IM′ with the shape of the master mold MM transferred thereto can be executed. Here, the second curable composition IM′ can be cured by applying curing energy CE such as light energy and/or heat energy to the second curable composition IM′. Then, as schematically shown in FIG. 13C, a step of obtaining a replica mold RM, that can be used as the mold M, by separating the master mold MM from the replica structure RS can be executed. The blank mold BM is a member that supports the replica structure RS.

The manufacturing method of the light emitting device 1 may further include a preparation step of preparing the master structure. The master mold MM as an example of the master structure can be formed by, for example, processing a quartz member by a photolithography process or the like.

The master structure may be formed using, for example, a structure where a plurality of reflecting members 121 are formed on the substrate 100. In this case, the preparation step can include a step of forming the plurality of reflecting members 121 on the substrate 100, and a layer stacking step of forming a stacked structure on the plurality of reflecting members 121 by repeating a film formation step, a photolithography step, and an etching step. This method is useful in a case of replacing a step of forming an optical adjustment film in the manufacturing method of the light emitting device 1, which is already in use, with the step of forming the insulating film 141 in this embodiment. Alternatively, in the photolithography step in the layer stacking step described above, an electron beam drawing apparatus may be used. In this case, it is unnecessary to manufacture a reticle for the photolithography step.

Each component will be exemplarily described in detail below.

### Configuration of Sub-Pixel (Organic Light Emitting Element)

The organic light emitting element as the sub-pixel 10 can be formed by using the lower electrode 131 as an anode and the upper electrode 153 as a cathode. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

The semiconductor substrate 101 may be changed to a non-semiconductor substrate such as quartz, glass, a silicon wafer, a resin, or a metal. In this case, a plurality of thin-film transistors can be formed on the non-semiconductor substrate. An insulating layer can be formed so as to cover the plurality of thin-film transistors, a wiring pattern can be arranged on the insulating layer, and an insulating layer can be further arranged on the wiring pattern. Contact holes can be formed in these insulating layers, and each contact hole can be filled with a plug. The insulating layer can be formed of, for example, a resin such as polyimide, silicon oxide, or silicon nitride.

### Electrode

Among the lower electrode and the upper electrode, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

As a reflective electrode, for example, chromium, aluminum, silver, titanium, copper, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be atop emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

In a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

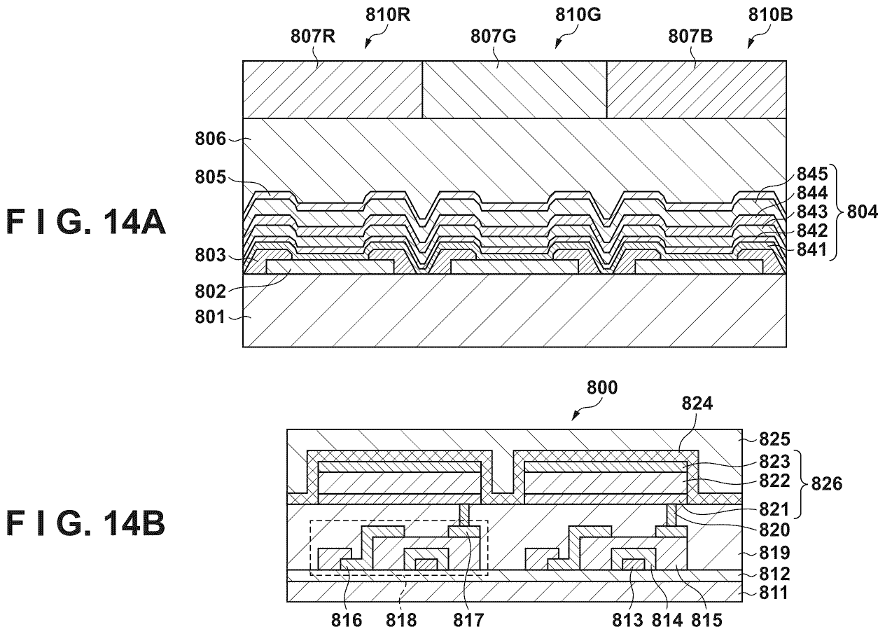

More details will be described next with reference to the accompanying drawings. FIG. 14A shows an example of the pixel. The pixel includes a plurality of sub-pixels 810 (pixels 150). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

FIG. 14B shows a part of the light emitting device 1 formed as a display device 800. FIG. 14B shows an organic light emitting element 826, and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 14B. That is, one of the anode and cathode and one of the source electrode and drain electrode of the TFT are electrically connected. The TFT indicates a thin-film transistor.

In the display device 800 shown in FIG. 14B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 14B, but may be used as another switching element instead.

The transistor used in the display device 800 shown in FIG. 14B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 14B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element is preferably provided on the silicon substrate.

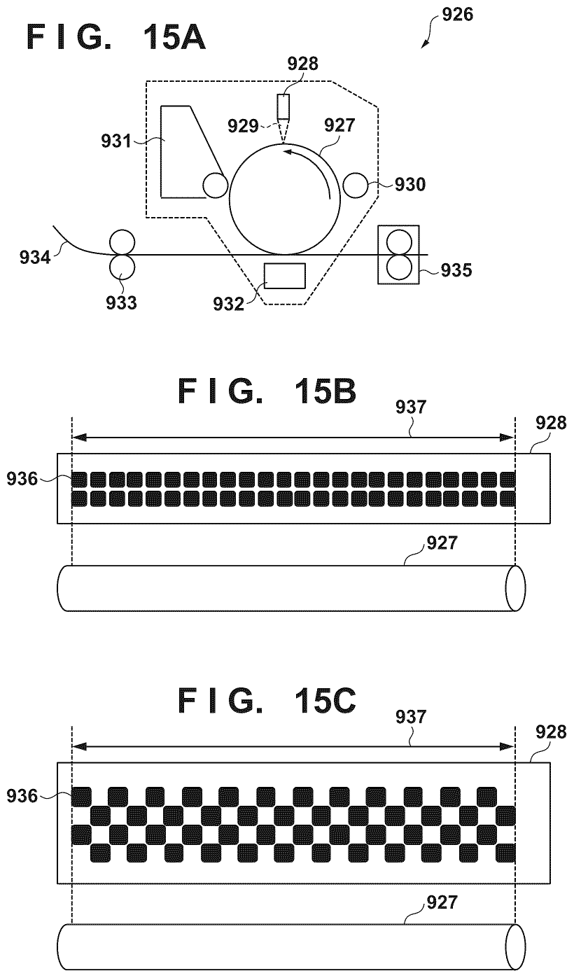

FIGS. 15A to 15C are schematic views showing an example of an image forming device using the light emitting device 1 according to this embodiment. An image forming device 926 shown in FIG. 15A includes a photosensitive member 927, an exposure light source 928, a developing unit 931, a charging unit 930, a transfer device 932, a conveyance unit 933 (a conveyance roller in the arrangement shown in FIG. 15A), and a fixing device 935.

Light 929 is emitted from the exposure light source 928, and an electrostatic latent image is formed on the surface of the photosensitive member 927. The light emitting device 1 can be applied to the exposure light source 928. The developing unit 931 can function as a developing device that includes a toner or the like as a developing agent and applies the developing agent to the exposed photosensitive member 927. The charging unit 930 charges the photosensitive member 927. The transfer device 932 transfers the developed image to a print medium 934. The conveyance unit 933 conveys the print medium 934. The print medium 934 can be, for example, paper, a film, or the like. The fixing device 935 fixes the image formed on the print medium.

Each of FIGS. 15B and 15C is a schematic view showing a form in which a plurality of light emitting units 936 are arranged in the exposure light source 928 along the longitudinal direction of a long substrate. The light emitting device 1 can be applied to each of the light emitting units 936. That is, a plurality of the pixels 150 arranged in a pixel array 110 are arranged along the longitudinal direction of the substrate. A direction 937 is a direction parallel to the axis of the photosensitive member 927. This column direction matches the direction of the axis upon rotating the photosensitive member 927. This direction 937 can also be referred to as the long-axis direction of the photosensitive member 927.

FIG. 15B shows a form in which the light emitting units 936 are arranged along the long-axis direction of the photosensitive member 927. FIG. 15C shows a form, which is a modification of the arrangement of the light emitting units 936 shown in FIG. 15B, in which the light emitting units 936 are arranged in the column direction alternately between the first column and the second column. The light emitting units 936 are arranged at different positions in the row direction between the first column and the second column. In the first column, the plurality of light emitting units 936 are arranged apart from each other. In the second column, the light emitting unit 936 is arranged at the position corresponding to the space between the light emitting units 936 in the first column. Furthermore, in the row direction, the plurality of light emitting units 936 are arranged apart from each other. The arrangement of the light emitting units 936 shown in FIG. 15C can be referred to as, for example, an arrangement in a grid pattern, an arrangement in a staggered pattern, or an arrangement in a checkered pattern.

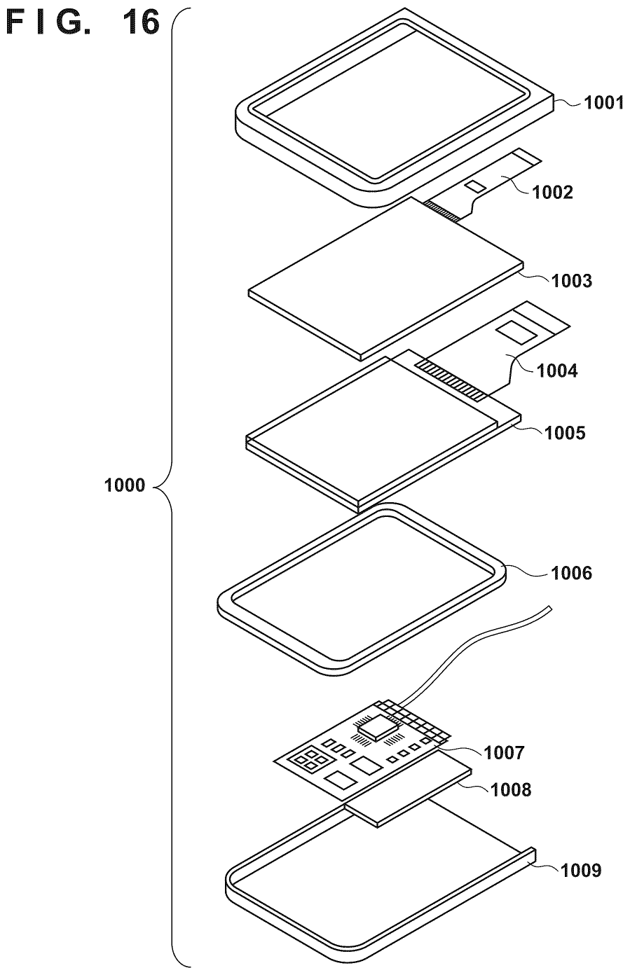

FIG. 16 is a schematic view showing an example of the display device using the light emitting device 1 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. Active elements such as transistors are arranged on the circuit board 1007. The battery 1008 is unnecessary if the display device 1000 is not a portable apparatus. Even when the display device 1000 is a portable apparatus, the battery 1008 need not be provided at this position. The light emitting device 1 can be applied to the display panel 1005. The pixels 150 arranged in the light emitting device 1 functioning as the display panel 1005 are connected to the active elements such as transistors arranged on the circuit board 1007 and operate.

The display device 1000 shown in FIG. 16 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

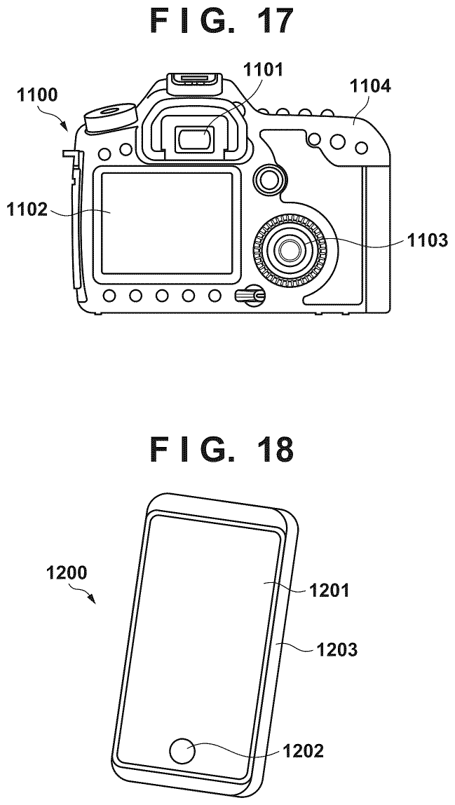

FIG. 17 is a schematic view showing an example of the photoelectric conversion device using the light emitting device 1 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 1 according to this embodiment can be applied to the viewfinder 1101 or the rear display 1102 as a display unit. In this case, the pixel region of the light emitting device 1 can display not only an image to be captured but also environment information, image capturing instructions, and the like. Examples of the environment information are the intensity and direction of external light, the moving velocity of an object, and the possibility that an object is covered with an obstacle.

The timing suitable for image capturing is a very short time in many cases, so the information is preferably displayed as soon as possible. Therefore, the light emitting device 1 in which the pixel 150 including the light emitting element using the organic light emitting material such as an organic EL element is arranged in the pixel region may be used for the viewfinder 1101 or the rear display 1102. This is so because the organic light emitting material has a high response speed. The light emitting device 1 using the organic light emitting material can be used for the devices that require a high display speed more preferably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 1 may be applied to a display unit of an electronic apparatus. At this time, the display unit can have both a display function and an operation function. Examples of the portable terminal are a portable phone such as a smartphone, a tablet, and a head mounted display.

FIG. 18 is a schematic view showing an example of an electronic apparatus using the light emitting device 1 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 1 according to this embodiment can be applied to the display unit 1201.

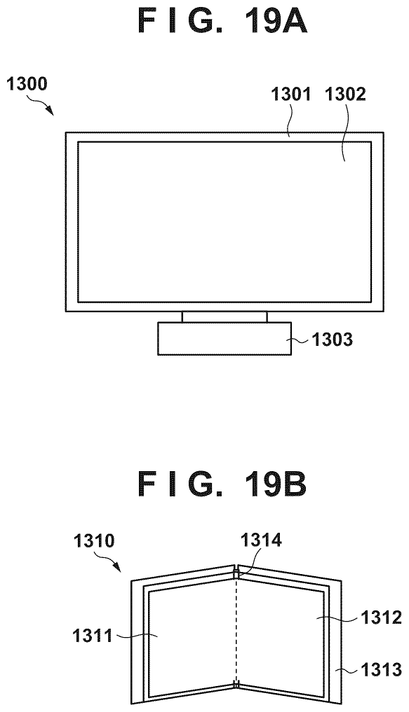

FIGS. 19A and 19B are schematic views showing examples of the display device using the light emitting device 1 according to this embodiment. FIG. 19A shows a display device such as a television monitor or a PC monitor. A display device 1300 includes a frame 1301 and a display unit 1302. The light emitting device 1 according to this embodiment can be applied to the display unit 1302. The display device 1300 can include a base 1303 that supports the frame 1301 and the display unit 1302. The base 1303 is not limited to the form shown in FIG. 19A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 19B is a schematic view showing another example of the display device using the light emitting device 1 according to this embodiment. A display device 1310 shown in FIG. 19B can be folded, and is a so-called foldable display device. The display device 1310 includes a first display unit 1311, a second display unit 1312, a housing 1313, and a bending point 1314. The light emitting device 1 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

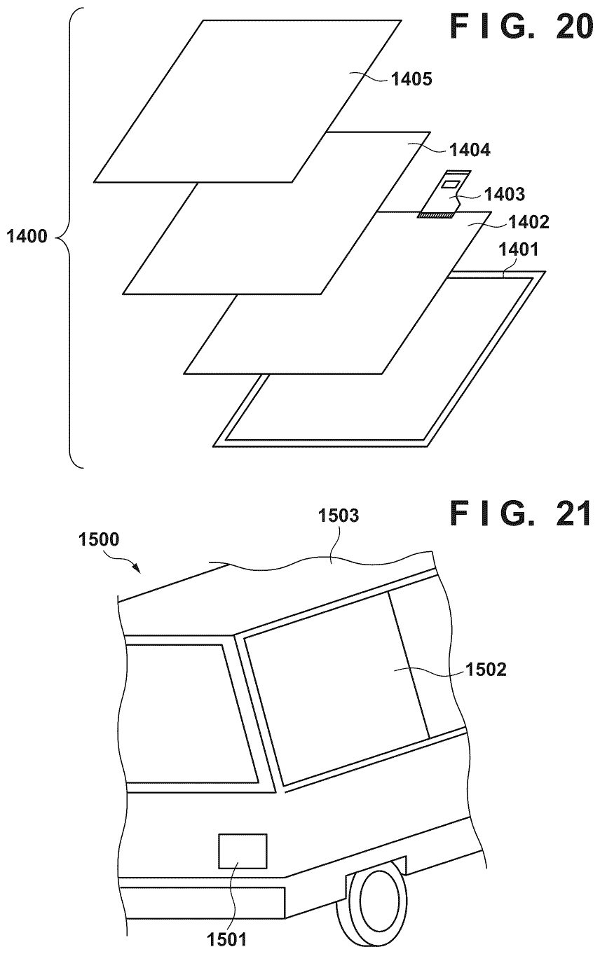

FIG. 20 is a schematic view showing an example of the illumination device using the light emitting device 1 according to this embodiment. An illumination device 1400 can include a housing 1401, a light source 1402, a circuit board 1403, an optical film 1404, and a light diffusing unit 1405. The light emitting device 1 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 1 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 21 is a schematic view of an automobile having a taillight as an example of a vehicle lighting appliance using the light emitting device 1 according to this embodiment. An automobile 1500 has a taillight 1501, and can have a form in which the taillight 1501 is turned on when performing a braking operation or the like. The light emitting device 1 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 1 according to this embodiment can be applied to the taillight 1501. The taillight 1501 can include a protection member for protecting the light emitting device 1 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 1 according to this embodiment may be used. In this case, the constituent materials of the electrodes and the like of the light emitting device 1 are formed by transparent members.

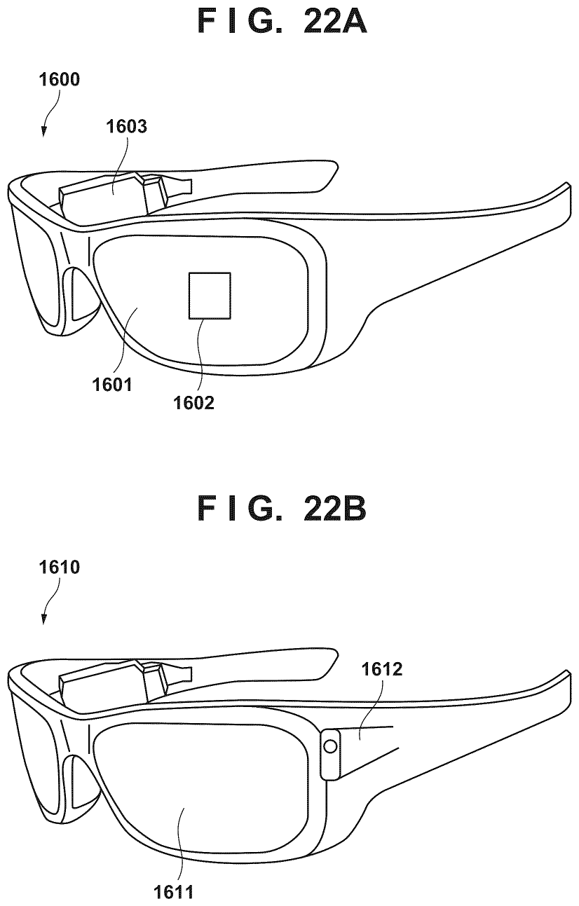

Further application examples of the light emitting device 1 according to this embodiment will be described with reference to FIGS. 22A and 22B. The light emitting device 1 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 22A. An image capturing device 1602 such as a CMOS sensor or an SPAD is provided on the surface side of a lens 1601 of the glasses 1600. In addition, the light emitting device 1 according to this embodiment is provided on the back surface side of the lens 1601.

The glasses 1600 further include a control device 1603. The control device 1603 functions as a power supply that supplies electric power to the image capturing device 1602 and the light emitting device 1 according to each embodiment. In addition, the control device 1603 controls the operations of the image capturing device 1602 and the light emitting device 1. An optical system configured to condense light to the image capturing device 1602 is formed on the lens 1601.

Glasses 1610 (smartglasses) according to one application example will be described with reference to FIG. 22B. The glasses 1610 include a control device 1612, and an image capturing device corresponding to the image capturing device 1602 and the light emitting device 1 are mounted on the control device 1612. The image capturing device in the control device 1612 and an optical system configured to project light emitted from the light emitting device 1 are formed in a lens 1611, and an image is projected to the lens 1611. The control device 1612 functions as a power supply that supplies electric power to the image capturing device and the light emitting device 1, and controls the operations of the image capturing device and the light emitting device 1. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 1 according to the embodiment of the present disclosure can include an image capturing device including a light receiving element, and control a displayed image based on the line-of-sight information of the user from the image capturing device.

More specifically, the light emitting device 1 decides a first visual field region at which the user is gazing and a second visual field region other than the first visual field region based on the line-of-sight information. The first visual field region and the second visual field region may be decided by the control device of the light emitting device 1, or those decided by an external control device may be received. In the display region of the light emitting device 1, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 1, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 1, the image capturing device, or an external device. If the external device holds the AI program, it is transmitted to the light emitting device 1 via communication.

When performing display control based on line-of-sight detection, smartglasses further including an image capturing device configured to capture the outside can be applied. The smartglasses can display captured outside information in real time.

### (Others)

While the present disclosure has been described with reference to exemplary embodiments, it is to be understood that the present disclosure is not limited to the disclosed exemplary embodiments. The scope of the following claims is to be accorded the broadest interpretation so as to encompass all such modifications and equivalent structures and functions.

According to the present disclosure, there is provided a technique advantageous in reducing the manufacturing cost of a light emitting device in which the distance between a lower electrode and a reflecting member is different among sub-pixels that emit light components of different colors.

This application claims the benefit of Japanese Patent Application No. 2024-171516, filed Sep. 30, 2024, which is hereby incorporated by reference herein in its entirety.

What is claimed is:

1. A light emitting device that includes a plurality of sub-pixels each including a lower electrode and an upper electrode, the plurality of sub-pixels including a first sub-pixel and a second sub-pixel, the first sub-pixel including a first reflecting member below a first lower electrode serving as a lower electrode of the first sub-pixel, and the second sub-pixel including a second reflecting member below a second lower electrode serving as a lower electrode of the second sub-pixel, the device comprising
an insulating film covering the first reflecting member and the second reflecting member,
wherein the insulating film is formed of a cured product of a curable composition,
the insulating film includes a first portion arranged between the first reflecting member and the first lower electrode, and a second portion arranged between the second reflecting member and the second lower electrode, and
a thickness of the first portion and a thickness of the second portion are different from each other.

2. The device according to claim 1, wherein
a spacing between the first reflecting member and the first lower electrode and a spacing between the second reflecting member and the second lower electrode are different from each other.

3. The device according to claim 1, wherein
the plurality of sub-pixels further include a third sub-pixel, and the third sub-pixel includes a third reflecting member below a third lower electrode serving as a lower electrode of the third sub-pixel,
the insulating film further includes a third portion arranged between the third reflecting member and the third lower electrode, and
a thickness of the first portion, a thickness of the second portion, and a thickness of the third portion are different from each other.

4. The device according to claim 3, wherein
a spacing between the first reflecting member and the first lower electrode, a spacing between the second reflecting member and the second lower electrode, and a spacing between the third reflecting member and the third lower electrode are different from each other.

5. The device according to claim 1, further comprising
a mold release agent film arranged between the insulating film and the lower electrodes of the plurality of sub-pixels.

6. The device according to claim 1, wherein
the first reflecting member is electrically connected to a lower electrode of the first sub-pixel arranged above the first reflecting member, and the second reflecting member is electrically connected to a lower electrode of the second sub-pixel arranged above the second reflecting member.

7. The device according to claim 3, wherein
the first reflecting member is electrically connected to an upper electrode of the first sub-pixel arranged above the first reflecting member, the second reflecting member is electrically connected to an upper electrode of the second sub-pixel arranged above the second reflecting member, and the third reflecting member is electrically connected to an upper electrode of the third sub-pixel arranged above the third reflecting member.

8. The device according to claim 1, wherein
the upper electrodes of the plurality of sub-pixels are provided commonly in the plurality of sub-pixels, and a fixed potential is applied thereto.

9. The device according to claim 1, wherein
the first reflecting member and the second reflecting member are arranged on an upper surface of a substrate,
the insulating film includes a connecting portion connecting the first portion and the second portion, and
a distance between the upper surface of the connecting portion and the upper surface of the substrate is larger than a distance between an upper surface of the first portion and the upper surface of the substrate and a distance between an upper surface of the second portion and the upper surface of the substrate.

10. The device according to claim 9, wherein
an upper surface of the insulating film includes tapered surfaces between an upper surface of the connecting portion and the upper surface of the first portion and between an upper surface of the connecting portion and the upper surface of the second portion.

11. The device according to claim 3, wherein
the first reflecting member, the second reflecting member, and the third reflecting member are arranged on an upper surface of a substrate,
the insulating film includes a connecting portion connecting the first portion, the second portion, and the third portion, and
a distance between the upper surface of the connecting portion and the upper surface of the substrate is larger than a distance between an upper surface of the first portion and the upper surface of the substrate, a distance between an upper surface of the second portion and the upper surface of the substrate, and a distance between an upper surface of the third portion and the upper surface of the substrate.

12. The device according to claim 11, wherein
an upper surface of the insulating film includes tapered surfaces between an upper surface of the connecting portion and the upper surface of the first portion, between an upper surface of the connecting portion and the upper surface of the second portion, and between an upper surface of the connecting portion and the upper surface of the third portion.

13. The device according to claim 1, further comprising
a second insulating film arranged between the insulating film and the lower electrodes of the plurality of sub-pixels.

14. The device according to claim 13, wherein
the second insulating film includes an inorganic film.

15. A display device comprising a light emitting device defined in claim 1, and an active element connected to the light emitting device.

16. An electronic apparatus comprising a housing provided with a display unit, and a communication unit provided in the housing and configured to perform external communication,
wherein the display unit includes a light emitting device defined in claim 1.

17. A manufacturing method of a light emitting device, comprising:
forming, on a substrate, a first reflecting member of a first sub-pixel and a second reflecting member of a second sub-pixel;
arranging a curable composition on the substrate;
bringing a mold into contact with the curable composition;
forming an insulating film formed of a cured product of the curable composition by curing the curable composition in a state in which the curable composition and the mold are in contact with each other;
separating the mold from the insulating film; and
forming a first lower electrode and a second lower electrode arranged above the first reflecting member and the second reflecting member, respectively, via the insulating film;
wherein the insulating film includes a first portion arranged between the first reflecting member and the first lower electrode, and a second portion arranged between the second reflecting member and the second lower electrode, and
a thickness of the first portion and a thickness of the second portion are different from each other.

18. The method according to claim 17, wherein
the insulating film includes a connecting portion connecting the first portion and the second portion, and
an upper surface of the insulating film includes tapered surfaces between an upper surface of the connecting portion and the upper surface of the first portion and between an upper surface of the connecting portion and the upper surface of the second portion.

19. The method according to claim 17, further comprising
replicating a master structure by an imprint process to form the mold.

20. The method according to claim 19, wherein
the replicating includes
making the master structure and a blank mold face each other via a second curable composition,
forming a replica structure formed of a cured film of the second curable composition with a shape of the master structure transferred thereto by curing the second curable composition, and
obtaining the mold by separating the master structure from the replica structure.

21. The method according to claim 19, further comprising
preparing the master structure,
wherein the preparing includes
forming a plurality of reflecting members on a substrate, and
forming a stacked structure on the plurality of reflecting members by repeating film formation, photolithography, and etching.
